(19) United States
(12) Patent Application Publication
(10) Pub. No.: US 2002/0024297 A1
(43) Pub. Date: Feb. 28, 2002

(54) Multiple layer organic thin films

(76) Inventors: Hoi-Sing Kwok, Hong Kong (HK); Li-Duo Wang, Hong Kong (HK)

Correspondence Address: BURNS DOANE SWECKER & MATHIS L L P, POST OFFICE BOX 1404, ALEXANDRIA, VA, 22313-1404, US

(21) Appl. No.: 09/908,814

(22) Filed: Jul. 20, 2001

Related U.S. Application Data
(63) Continuation-in-part of application No. 09/420,792, filed on Oct. 19, 1999.

(51) Int. Cl. H01J 1/62; H01J 63/04; B32B 9/00; B32B 19/00

(52) U.S. Cl. 313/504; 428/690

(57) ABSTRACT

Pulsed laser deposition is used to deposit organic thin films, in particular of materials that are of interest to display applications. Luminescent films such as tris-(8-hydroxyquinoline)aluminum (Alq3 ) can be deposited without degradation of their luminescent properties. Alternating layers of different materials, one of which is an organic compound and another of which is an inorganic material, can be deposited using this method. High luminescent efficiency multi-layer films can be obtained.

### FIELD OF THE INVENTION

This invention relates to multiple layer organic thin films, and to methods and apparatus for forming such multiple layer organic thin films.

### BACKGROUND OF THE INVENTION

Many organic materials are known for use in electroluminescent devices. Since the discovery of materials such as tris-(8-hydroxyquinoline) aluminium (Alq3) and N,N′-bis(3-methyl-phenyl)-(1,1′-biphenyl)4,4′-diamine (TPD) more than 10 years ago, many processing techniques have been developed to produce thin films using these compounds. Common techniques include doctor blade coating, spin coating, spin casting and dip coating. Recently thermal evaporation in a vacuum chamber has been found to be a good method for producing such films.

Methods such as dip coating, doctor blade and spin casting can only deposit thick films of over 1 micron in thickness, whereas in many applications in organic electroluminescent devices the layer must be less than 1 micron. Thermal evaporation is one of the few techniques available for producing suitable thin organic films, and more recently ion assisted deposition (IAD) has also been attempted with some success.

The performance of any thin film device will depend strongly on the quality of the thin film, and it is important therefore to explore novel deposition techniques and novel structures for organic thin film devices.

### SUMMARY OF THE INVENTION

According to the present invention there is provided a thin film device comprising a multilayer structure of alternating layers of organic and inorganic materials deposited on a substrate. In particular the device may be a thin film electroluminescent device such as a light emitting diode. Preferably therefore the device may further comprise electrode layers sandwiching said layers or organic and inorganic materials.

The alternating layers of organic and inorganic materials may be formed by pulsed laser deposition or by thermal evaporation.

The organic material may be selected from the group consisting of tris-(8-hydoxyquinoline)aluminium (Alq3), 2-(4-biphenyl)-5(4-tert-phenyl)-1,3,3-oxadiazole (PBD), N,N′-bis(3-methyl-phenyl)-(1,1′-biphenyl)4,4′-diamine (TPD), 2-(4-biphenyl)-5-(4-tert-butylphenyl)-1,3,4-oxydiazole (PBD), N,N′-bis (2,5-di-tertbutylphenyl)-3,4,9,10-perylenedicarboximide (BPPC), 4,4′,4″-(tris(3-methyphenylphenylamino)triphenylamine (m-MTDATA), 1,2,3,4,5-pentaphenyl-1,3-cyclopentadiene (PPCP) bis-(triphenyl)diamine (TAD), 1,2,4-trizole (petTAZ), 2-naphthyl-4,5-bis(4-methoxyphenyl)-1,3-oxazole (NAPOXA), perylene bisimide pigment (PBP), and tris-(1-phenyl-3-methyl-4-isobutyryl-5-pyrozolone)-bis(triphenyl phosphine oxide) terbium (PTT).

The inorganic material is selected from the group consisting of gallium phosphide, gallium nitride, silicon, silicon oxide, aluminium oxide, tin oxide, indium oxide, magnesium oxide, indium tin oxide, zinc oxide or zinc sulfide.

Particularly preferred combinations of organic and inorganic layers include Alq3/GaP and TPD/GaN.

### BRIEF DESCRIPTION OF THE DRAWINGS

Some embodiments of the invention will now be described by way of example and with reference to the accompanying drawings, in which:

FIG. 1 shows schematically an apparatus for forming a thin film device according to an embodiment of the invention,

FIG. 2 shows the micro-Raman spectra of an Alq3 target (upper curve) and the Alq3 thin film (lower curve) with an arbitrary vertical scale,

FIG. 3 shows the XPS spectra of the Alq3 target (dotted curves) and the Alq3 thin film (solid curves) with an arbitrary vertical scale,

FIG. 4 shows the photoluminescence spectra of the Alq3 thin film (lower curve) and the target (upper curve) with an arbitrary vertical scale,

FIG. 5 shows the photoluminescence spectra of a TPD thin film (lower curve) and the target (upper curve) with an arbitrary vertical scale,

FIG. 6 shows the photoluminescence spectra of the single layer Alq3 thin film (lower curve) and the multiple layer Alq3 /GaP film (upper curve),

FIG. 7 shows the current-voltage characteristic of a thin film device according to a first embodiment of the present invention, and

FIG. 8 shows the emission spectra of the device of the first embodiment at bias voltages of 10 V and 12 V.

### DETAILED DESCRIPTION OF PREFERRED EMBODIMENTS

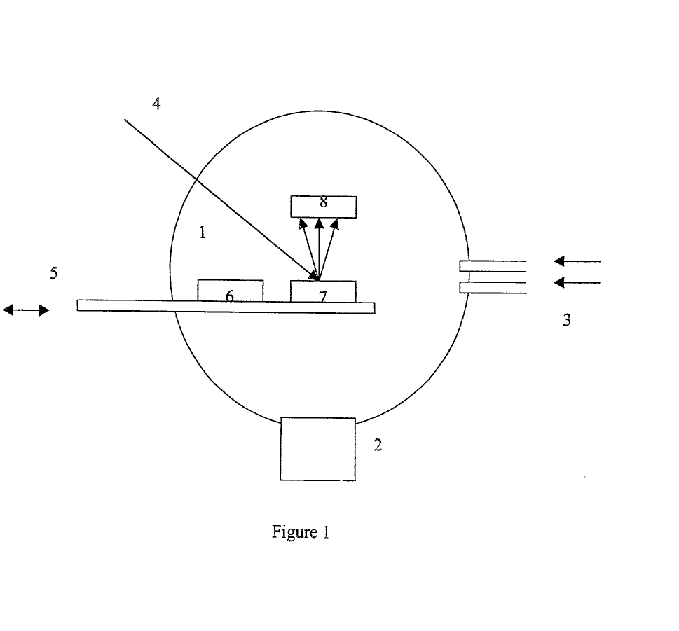

FIG. 1 shows schematically apparatus for forming an organic thin film layer in accordance with an embodiment of the invention. The apparatus comprises a standard vacuum chamber 1 capable of a base pressure of 10⁻⁵ torr, an excimer laser such as an ArF laser with an output 4 at 193 nm, a laser target 6 for ablation, a target rotator 5 to rotate the target to avoid excessive localised exposure of the target, a substrate held by a substrate holder 8, a substrate heater/cooler for controlling the temperature of the substrate, and gas inlets 3 into the vacuum chamber to regulate the deposition pressure. A set of mirrors and lenses may also be provided to control the position and focus of the laser beam. A pump 2 is provided to pump the chamber to a desired vacuum. A second target 7 is provided for the formation of multiple layers of alternating materials as will be discussed below.

In a first example, the target may be a cold pressed pellet of Alq3 . The laser is rastered on the target to avoid deterioration. In this way the target irradiation is made more uniform. In addition the target itself is rotated so that a single location on the target is not always being irradiated. The substrate is glass coated with indium tin oxide (ITO). The deposition is carried out at room temperature and the chamber was filled with nitrogen to a pressure of 20 mtorr during the deposition. The deposition laser fluence was about 0.64J/cm² at 10 Hz. The fluence is chosen to have a reasonable deposition rate while minimising decomposition of the target. The fluence needs to be selected carefully as if it is too high the film may be charred, while if it is too low the deposition rate will be too low for practical applications. A deposition rate of 8.3 pm/pulse at the laser fluence used was measured using an alpha step profilometer.

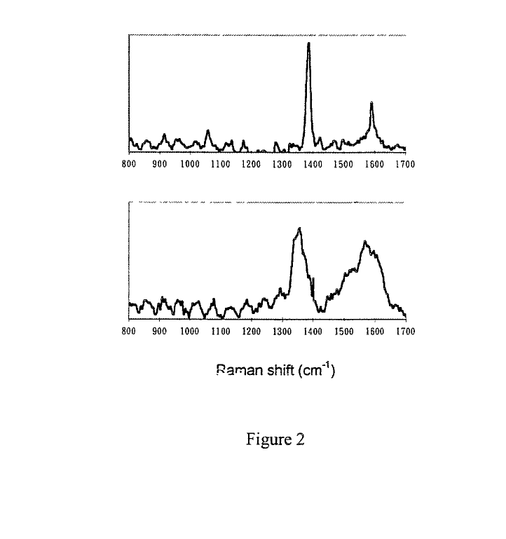

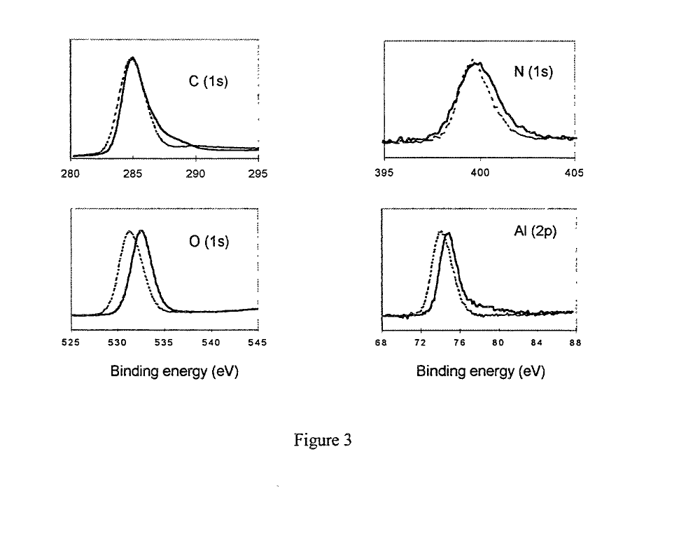

Several techniques may be used to characterise the deposited thin film, including micro-Raman spectroscopy and X-ray spectroscopy (XPS). The former is more sensitive to bulk material, while the latter is surface sensitive. The results on tests on a sample of 150 nm thin film are shown in FIGS. 2 and 3.

FIG. 2 shows the room temperature micro-Raman spectra of the Alq3 target (upper curve) and the Alq3 thin film (lower curve). It can be seen that the micro-Raman peaks of the target are at 1386 cm⁻¹ and 1591 cm⁻¹, while they are around 1357 cm⁻¹ and 1568 cm⁻¹ respectively for the Alq3 thin film. This is a blueshift of about 20-30 cm⁻¹ which indicates a slight change in the molecular bond strength or bond length that affects the vibrational frequencies.

Additionally, the relative heights of the peaks, as well as the linewidth, have changed between the target and the film. The wider linewidth for the peaks in the film indicate a higher degree of disorder induced inhomogeneous broadening.

FIG. 3 shows the XPS spectra for the Alq3 film (solid line) and the Alq3 target (broken lines). The XPS spectra are generally similar to those reported in the literature. Although there is some blueshift of the C, N, O and Al peaks of the film compared to the target, nonetheless there is generally a good match between the spectra of the target and the film.

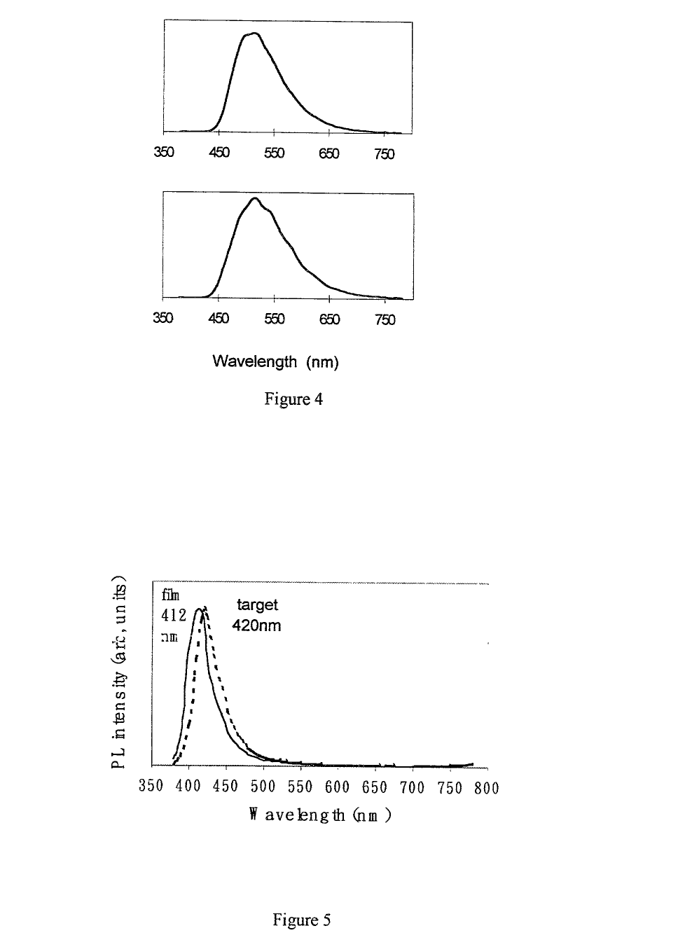

FIG. 4 (lower curve) shows the photoluminescence (PL) spectra of the Alq3 film using an excitation wavelength of 325 nm from a HeCd laser at room temperature. The upper curve of FIG. 4 shows the PL spectrum of the Alq3 target material. Both spectra are very close to the published literature. It can be seen that the photoluminescence of the thin Alq3 film is quite strong.

The results of the micro-Raman spectroscopy and the XPS analysis, together with the PL spectra show the pulsed laser deposition is clearly suitable for forming a thin organic layer of a material such as Alq3 with similar luminescent properties to the bulk material.

In addition to Alq3 , thin films of other organic material can also be formed by pulsed laser deposition. Examples are 2-(4-biphenyl)-5(4-tert-phenyl)-1,3,3-oxadiazole (PBD), N,N′-bis(3-methyl-phenyl)-(1,1′-biphenyl)4,4′-diamine (TPD), 2-(4-biphenyl)-5(4-tert-butylphenyl)-1,3,4-oxydiazole (PBD), N,N′-bis (2,5-di-tertbutylphenyl)-3,4,9,10-perylenedicarboximide (BPPC), 4,4′,4″-(tris(3-methyphenylphenylamino)triphenylamine (m-MTDATA), bis-(triphenyl)diamine (TAD), 1,2,4-trizole (p-etTAZ), 2-naphthyl-4,5-bis(4-methoxyphenyl)-1,3-oxazole (NAPOXA), perylene bisimide pigment (PBP), tris-(1-phenyl-3-methyl-4-isobutyryl-5-pyrozolone)-bis(triphenyl phosphine oxide) terbium (PTT), and others.

FIG. 5 shows the photoluminescence spectra for a thin film of laser deposited TPD and the original TPD target which shows that a thin film of TPD can be successfully deposited by laser deposition.

In the apparatus shown in FIG. 1 provision is made for two targets to be provided. In a particularly preferred aspect of this invention, one of the targets may be an organic target as discussed above, while the other target may be an inorganic target such as a semiconductor material. Possible inorganic materials include, for example, gallium phosphide, gallium nitride, silicon, silicon oxide, aluminium oxide, tin oxide, indium oxide, magnesium oxide, indium tin oxide, and zinc oxide.

By depositing layers alternately from the organic and the inorganic target, a multilayer structure may be obtained alternating thin organic and inorganic films.

In one embodiment, for example, a structure alternating Alq3 /GaP/Alq3 /GaP was formed. The structure consisted of a total of 12 layers with each layer being 24 nm thick and the composite structure being 288 nm thick.

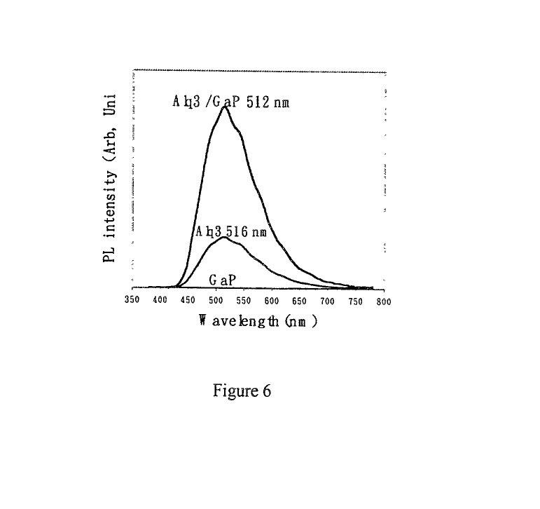

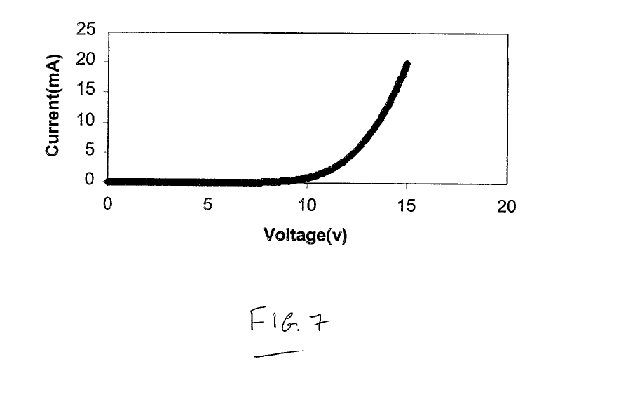

The deposition of the GaP layer is performed under similar conditions to the deposition of the Alg3 film except that the laser fluence must be adjusted. Two targets are placed in the vacuum chamber so that alternate deposition can be performed simply by shifting the laser beam from one target to the other. FIG. 6 shows the PL spectra of the multilayer structure together with that of a single layer Alq3 sample. It can be seen that the multilayer sample shows a photoluminescence that is three times stronger.

A further embodiment of the invention comprises an organic light emitting diode (OLED) comprising a multilayer structure consisting of alternate layers of TPD and an. The structure for the multilayer composite is ITO/CuPc/(TPD/GaN)ₙ/TPD/Ag. This is a multilayer structure that alternates TPD and GaN between ITO and Ag electrodes. The CoPc layer is an anode buffer layer that is used to facilitate hole injection. The layer in contact with the Ag electrode is always TPD which functions as a cathode buffer layer. In the formation of this multilayer structure the alternating layers may be formed either by pulsed laser deposition as discussed above, or alternatively if one or both of the targets in FIG. 1 is provided with a heating means, then one or both of the alternating layers may be formed by thermal evaporation.

In this embodiment n may vary between, for example 1 and 5, and n=2 is a preferred number. Optimal thicknesses for the layers are 2 nm for the TPD layers, 1.2 nm for the GaN layers, and 1 nm for the CuPc buffer layer.

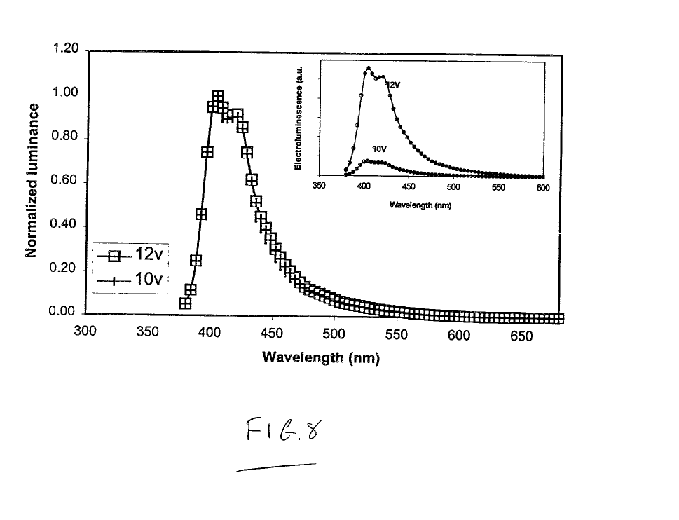

FIG. 7 shows the current-voltage characteristic of an OLED in accordance with this embodiment with n=2. The turn-on voltage of about 10 V is typical for a small molecule OLED. The emission spectra of the OLED at 10 V and 12 V bias are shown in FIG. 8. The normalized spectra at these bias voltages are identical. The emission peak is at 400 nm, with another smaller peak at 320 nm. This photoluminescence spectra is very similar to the spectra of pure TPD showing that the emission is from the TPD alone. The emission is chiefly within the UV spectrum with some emission in the blue-green visible spectrum.

With n 0 or 1 emission is very weak, while with n >2 the threshold current becomes very high and over 20 V is needed to obtain emission.

1. A thin film device comprising a multilayer structure of alternating layers of organic and inorganic materials deposited on a substrate.

2. A device as claimed in claim 1 further comprising electrode layers sandwiching said layers or organic and inorganic materials.

3. A device as claimed in claim 1 wherein the alternating layers of organic and inorganic materials are formed by pulsed laser deposition or by thermal evaporation.

4. A device as claimed in claim 1 wherein the organic material is selected from the group consisting of tris-(8-hydoxyquinoline)aluminium (Alq3 ), 2(4-biphenyl)-5(4-tert-phenyl)-1,3,3-oxadiazole (PBD), N,N′-bis(3-methylphenyl)-(1,1′-biphenyl)4,4′-diamine (TPD), 2-(4-biphenyl)-5-(4-tertbutylphenyl)-1,3,4-oxydiazole (PBD), N,N′-bis(2,5-di-tert-butylphenyl)3,4,9,10-perylenedicarboximide (BPPC), 4,4′,4″-(tris(3-methyphenylphenylamino)triphenylamine (m-MTDATA), 1,2,3,4,5-pentaphenyl-1,3-cyclopentadiene (PPCP) bis-(triphenyl)diamine (TAD), 1,2,4-trizole (p-etTAZ), 2-naphthyl-4,5-bis(4-methoxyphenyl)-1,3-oxazole (NAPOXA), perylene bisimide pigment (PBP), and tris-(1-phenyl-3-methyl-4-isobutyryl-5-pyrozolone)-bis(triphenyl phosph ine oxide) terbium (PTT).

5. A device as claimed in claim 1 wherein the inorganic material is selected from the group consisting of gallium phosphide, gallium nitride, silicon, silicon oxide, aluminium oxide, tin oxide, indium oxide, magnesium oxide, indium tin oxide, zinc oxide or zinc sulfide.

6. A device as claimed in claim 1 wherein said organic material is tris-(8-hydroxyquinoline)aluminium, and the inorganic material is gallium phosphide.

7. A device as claimed in claim 1 wherein the organic material is N,N′-bis(3-methyl-phenyl)-(1,1′-biphenyl)-4,4′-diamine, and the inorganic material is gallium nitride.

8. A device as claimed in claim 7 comprising n pairs of organic and inorganic layers where 1 <n <5.

9. A device as claimed in claim 8 where n =2.

10. A device as claimed in claim 7 including an indium tin oxide anode layer, and a Ag cathode layer, and wherein a layer of organic material is in contact with said cathode layer.

11. A device as claimed in claim 10 further comprising a CuPc anode buffer layer.
